(19) United States
(12) Patent Application Publication
(10) Pub. No.: US 2020/0091363 A1
(43) Pub. Date: Mar. 19, 2020

(54) NOVEL LIGHTING SYSTEM USING A SOLAR COLLECTOR PANEL

(71) Applicant: Arun K. Gupta, Dallas, TX (US)

(72) Inventor: Arun K. Gupta, Dallas, TX (US)

(21) Appl. No.: 16/566,859

(22) Filed: Sep. 10, 2019

Related U.S. Application Data
(60) Provisional application No. 62/731,060, filed on Sep. 13, 2018.

(51) Int. Cl. H01L 31/054; H02S 40/44; F24S 23/70; F24S 30/455; F24S 50/20

(52) U.S. Cl. CPC H01L 31/0547; H02S 40/44; F24S 23/70; F24S 2023/87; F24S 50/20; F24S 2023/84; F24S 30/455

(57) ABSTRACT

A novel lighting system includes a solar collector panel comprising a plurality of reflector elements configured to track and be oriented optimally to receive electromagnetic radiation from the sun and reflect the received electromagnetic radiation toward a skylight in a roof of a building, a dichroic mirror disposed in the skylight and oriented and configured to receive the reflected electromagnetic radiation from the solar collector panel, the dichroic mirror being configured to reflect electromagnetic radiation of a first specific range of wavelengths downward into the building and pass through electromagnetic radiation of a second specific range of wavelengths, and a photovoltaic panel oriented and configured to receive electromagnetic radiation of the second specific range of wavelengths that passed through the dichroic mirror and convert it to electricity.

### RELATED APPLICATION

This non-provisional patent application claims the benefit of U.S. Provisional Patent Application No. 62/731,060 filed on Sep. 13, 2018, the entire contents of which are incorporated herein by reference.

### FIELD

The present disclosure relates generally to indoor lighting, and in particular to a novel lighting system using a solar collector panel.

### BACKGROUND

This application incorporates by reference U.S. Non-Provisional patent application Ser. No. 14/109,495, Publication No. US 2014/0166077, in its entirety.

### BRIEF DESCRIPTION OF THE DRAWINGS

FIGS. 1-3 are diagrams illustrating an exemplary embodiments of a novel lighting system according to the teachings of the present disclosure;

FIG. 4 is a perspective view of an exemplary embodiment of a solar collector panel of a novel lighting system according to the teachings of the present disclosure;

FIG. 5 is a perspective view of an exemplary embodiment of a reflector element in a solar collector panel of a novel lighting system according to the teachings of the present disclosure; and

FIG. 6 is a side view of an exemplary embodiment of a row of reflector elements in a solar collector panel of a novel lighting system according to the teachings of the present disclosure.

### DETAILED DESCRIPTION

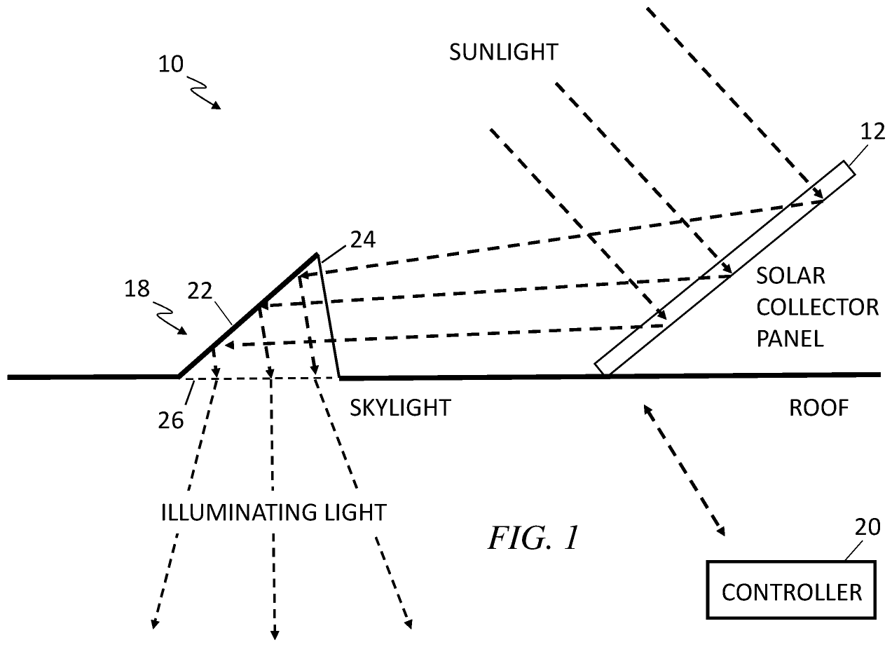

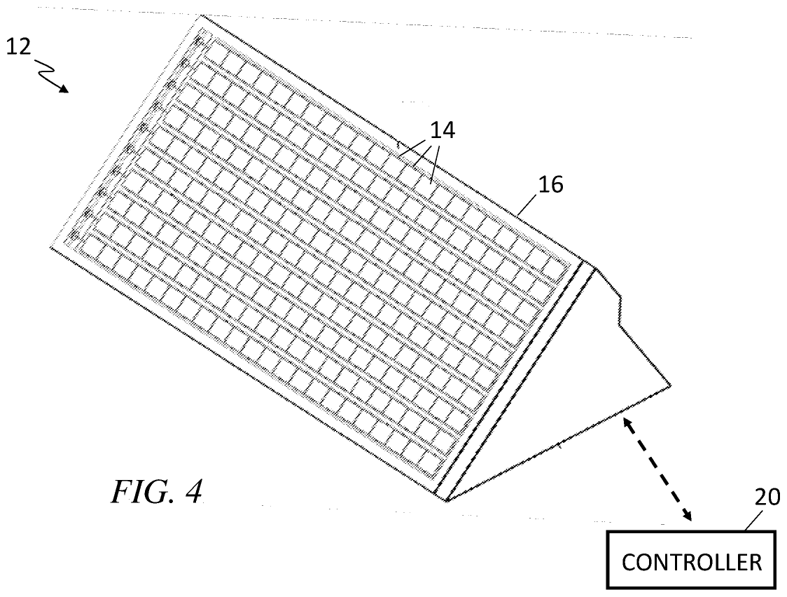

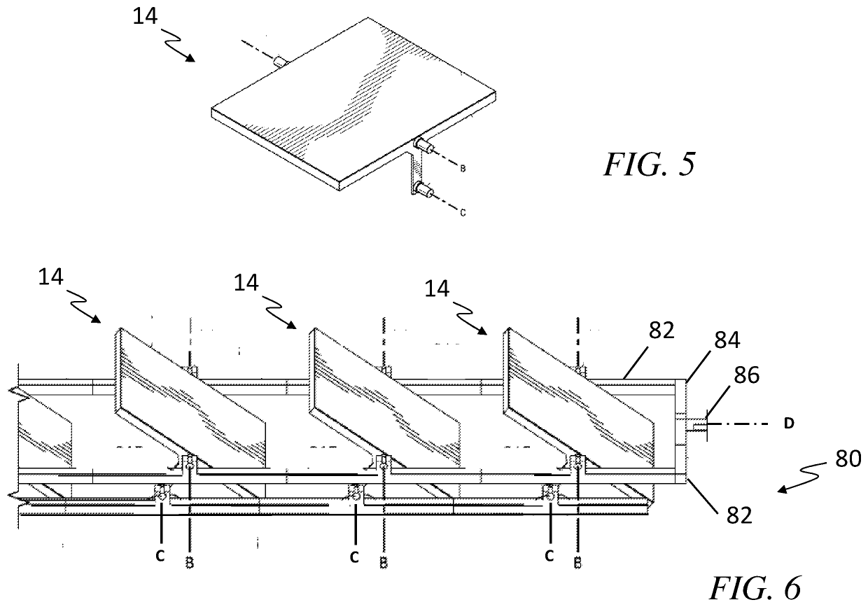

FIG. 1 is a diagram illustrating an exemplary embodiment of a novel lighting system 10 according to the teachings of the present disclosure. The novel lighting system 10 includes a solar collector panel 12 that comprises a plurality of reflector elements 14 arranged in a matrix configuration (i.e., rows and columns) within a frame 16 (FIG. 4). The reflector elements 14 can be controllably moved such that they are always oriented to optimally direct sunlight (electromagnetic radiation) toward a mirror assembly 18 disposed in a skylight formed in the roof of a building. A microprocessor-based controller unit 20 is configured to issue instructions to change the orientation of the reflector elements 14 in the solar collector panel 12 so that they are optimally arranged with respect to the position of the sun in the sky. An exemplary embodiment of the assembly for controllably orient and direct the reflector elements 14 within the matrix is set forth below with references to FIGS. 5 and 6, and is also described in U.S. Non-Provisional patent application Ser. No. 14/109,495, Publication No. US 2014/0166077. The solar collector panel 12 may have a linear or spot focus. The mirror assembly 18 includes a mirror 22 oriented at an acute angle so that it reflects and disperses light from the solar collector panel 12 downward and thus provides illumination in the interior of the building. The mirror 22 may have a specific contour (e.g., concave, convex, parabolic, irregular, flat, etc.) that provides the desired focus and dispersion of the light into the building. The mirror assembly 18 further includes a substantially transparent incident light pane 24 that is oriented toward the solar collector panel 12, and a substantially horizontally-oriented diffuser pane 26 that enclose the mirror assembly space into which light is reflected. The incident light pane 24 may be constructed of glass, acrylic, and other light-admitting materials. Similarly, the diffuser pane 26 may be constructed of glass, acrylic, and other light-diffusing and translucent materials.

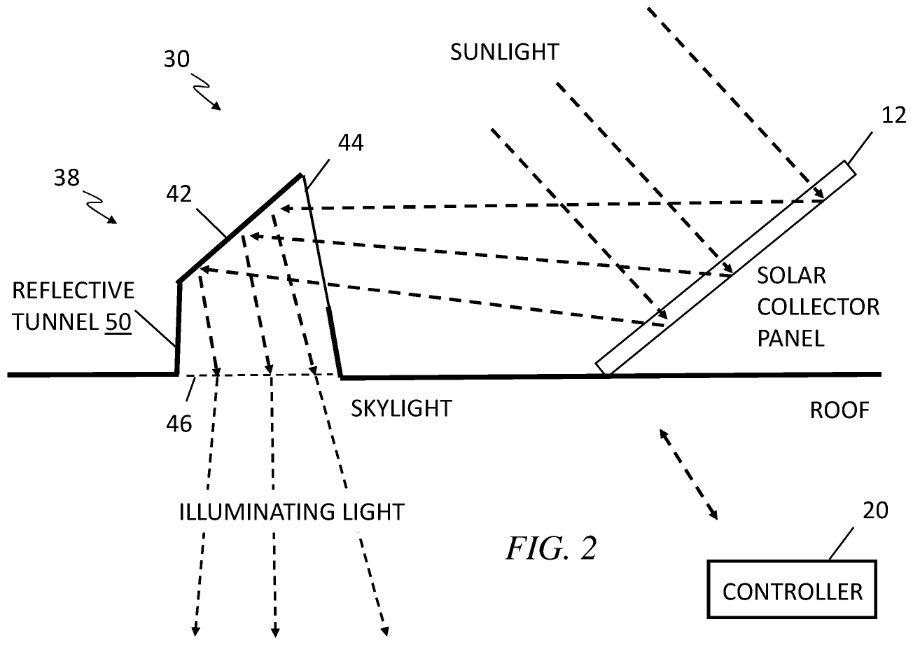

FIG. 2 is a diagram illustrating another exemplary embodiment of a novel lighting system 30 according to the teachings of the present disclosure. This embodiment of the novel lighting system 30 includes a solar collector panel 12 that comprises a plurality of reflector elements 14 arranged in a matrix within a frame 16 (see FIG. 4). The reflector elements 14 can be controllably moved by a controller 20 such that they are always oriented to optimally direct sunlight toward a mirror 42 through a glass pane 44 disposed in a skylight 38 formed in the roof of a building. The solar collector panel 32 may have a linear or spot focus. The mirror 42 is oriented so that it reflects and disperses light downward and thus provides illumination in the interior of the building. In this embodiment, the mirror 42 is elevated off of the plane of the roof, so that a “tunnel” 50 connecting the mirror 42 to the roof preferably incorporates reflective surfaces to propagate light along the tunnel 50 and into the building. The tunnel 50 may extend below the roof line into the building to extend the propagation distance. The mirror 42 may have a specific contour (e.g., concave, convex, parabolic, irregular, flat, etc.) that provides the desired focus and dispersion of the light into the building.

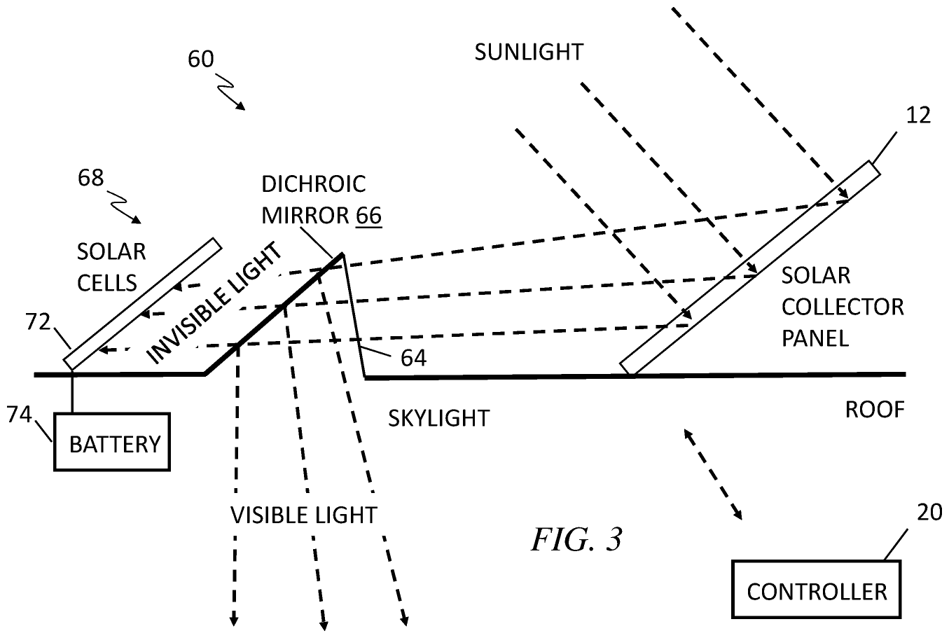

FIG. 3 is a diagram illustrating yet another exemplary embodiment of a novel lighting system 60 according to the teachings of the present disclosure. The novel lighting system 60 includes a solar collector panel 12 that comprises a plurality of reflector elements 14 arranged in a matrix within a frame 16 (FIG. 4). The reflector elements 14 can be controllably moved by a controller 20 such that they are oriented to optimally direct sunlight (electromagnetic radiation) toward a dichroic mirror 66 through a pane of glass 64 disposed in a skylight 68 formed in the roof of a building. The solar collector panel 62 may have a linear or spot focus. The dichroic mirror 66 can be an integral part of the skylight or be positioned proximate to the skylight structure to perform this function. The dichroic mirror 66 has significantly different reflection and transmission properties at two different wavelengths. The dichroic mirror 66 is tuned and fabricated to reflect light of a first specific range of wavelengths and allowed to pass through light of a second specific range of wavelengths. More specifically, the dichroic mirror 66 reflects all or a majority of the visible light (400-700 nm) and transmits all or a majority of the invisible light (700-1190 nm). The dichroic mirror 66 reflects and directs the visible light downward through the skylight in the roof, thus providing illumination to the interior of the building. The invisible light that passes through the dichroic mirror 66 is allowed to reach a solar panel 72 comprising a plurality of solar (photovoltaic) cells and electrically coupled to a battery storage system 74. The solar cells in the solar panel 72 perceive the invisible light and convert the light energy to electricity, which is stored in a battery storage system, and/or conveyed to the electrical grid after DC to AC conversion. The solar energy generation system includes one or more solar panels, a solar charge controller, and a battery storage system. An inverter circuit may be used to convert the DC power generated by the solar energy generation system to AC power for use by electrical appliances and devices, and for the electrical grid.

In an exemplary embodiment of the novel lighting systems described herein, the glass pane in the skylight and/or the solar collector panel may be fabricated with a coating that blocks electromagnetic radiation of a certain wavelength, such as infrared (IR) and/or ultraviolet (UV) light to diminish or eliminate unwanted heating in the building and UV exposure to persons inside the building. As shown in FIGS. 1 and 2, an optional light diffuser may also be employed to more evenly disperse the visible light over a wider angle. Further, the back panel of the photovoltaic panel may possess thermal conductive properties so that it may serve as a heat sink to help dissipate heat generated within the photovoltaic panel.

FIG. 4 is a perspective view of an exemplary embodiment of a solar collector panel 12 of a novel lighting system according to the teachings of the present disclosure. The solar collector panel 12 comprises reflector elements 14 that can be oriented to track the sun such that no matter where the sun is in the sky, the reflector elements 14 reflects the rays of solar radiation toward the dichroic mirror. The solar collector panel 12 may be mounted on the roof of a building on top of a rack such that the solar collector panel is positioned at an angle, such as at 45 degrees from the horizontal. A controller 20 can be in wired or wireless communication with the reflector element control mechanism in the solar collector panel. Each row of reflector elements can be independently controlled and oriented to track the source of electromagnetic radiation. Further, dimming of the light level (lumens) may be achieved by defocusing one or more rows of the reflector elements away from the mirror. An app executing on a smartphone may be used by a user as an on/off and dimming control user interface, or commercial lighting control software may be used as a user interface.

FIG. 5 is a perspective view of an exemplary embodiment of a reflector element 14 in a solar collector panel 12 of a novel lighting system according to the teachings of the present disclosure. The reflector element 14 is preferably square and has a highly reflective surface. The reflector element surface may comprise a highly polished thin sheet of aluminum stamped to the desired size, shape and contour. The stamped reflective aluminum sheet can be mounted onto a base assembly (not shown) that is coupled to a mechanical drive system that can orient the surface of each reflector element in the solar collector panel in response to the position of the light source (sun).

FIG. 6 is a side view of an exemplary embodiment of a row of reflector elements 14 in a solar collector panel of a novel lighting system according to the teachings of the present disclosure. The reflector elements 14 are connected by a mechanical drive system 80 that allows the reflector elements 14 to move in unison about a set of parallel first axes B and move in unison about a second axis D, the second axis D Substantially orthogonal to the set of parallel first axes B. By enabling rotation about two axes, the reflector elements 14 are configured to track a moving electromagnetic radiation source such as the sun. The solar collector panel 12 preferably includes a plurality of rows of reflector elements forming a matrix (rows and columns). The reflector elements 14 may be suspended between a pair of upper rails 82 at regular intervals as shown in FIG. 4, but other configurations are contemplated. The upper rails 82 are connected with a crossbar 84, which maintains spacing between the upper rails 82 for positioning the reflector elements 14 therebetween. The crossbar 84 is attached to a rotational shaft 86, which is centered between the upper rails. Further details of an embodiment of the reflector element actuation configuration may be found in the prior application, U.S. Non-Provisional patent application Ser. No. 14/109,495, Publication No. US 2014/0166077.

The features of the present invention which are believed to be novel are set forth below with particularity in the appended claims. However, modifications, variations, and changes to the exemplary embodiments of a novel lighting system using a solar collector panel described above will be apparent to those skilled in the art, and the described herein thus encompasses such modifications, variations, and changes and are not limited to the specific embodiments described herein.

What is claimed is:

1. A novel lighting system comprising:
a solar collector panel comprising a plurality of reflector elements configured to track and be oriented optimally to receive electromagnetic radiation from the sun and reflect the received electromagnetic radiation toward a skylight in a roof of a building;
the skylight comprising a transparent window pane oriented toward the solar collector panel and a dichroic mirror disposed in the skylight and oriented and configured to receive the reflected electromagnetic radiation from the solar collector panel, the dichroic mirror being configured to reflect electromagnetic radiation of a first specific range of wavelengths downward into the building and pass through electromagnetic radiation of a second specific range of wavelengths; and
a photovoltaic panel oriented and configured to receive electromagnetic radiation of the second specific range of wavelengths that passed through the dichroic mirror and convert it to electricity.

2. The novel lighting system of claim 1, wherein the mirror is disposed in the skylight having reflective sides forming a reflective tunnel in the roof of the building.

3. The novel lighting system of claim 1, further comprising a battery electrically coupled to the photovoltaic panel for storing electricity generated by the photovoltaic panel.

4. The novel lighting system of claim 1, wherein the solar collector panel comprises the plurality of reflector elements arranged in a plurality of reflector arrays, each reflector array arranged along a longitudinal axis and pivotally mounted to at least one elongated member parallel to the longitudinal axis, where the plurality of reflector elements in each reflector array being configured to pivot simultaneously in unison; and
each of the plurality of reflector arrays being mounted to rotate about the longitudinal axis independently of the other reflector arrays, where each of the plurality of reflector elements in a reflector array being configured to rotate about the longitudinal axis simultaneously in unison.

5. The novel lighting system of claim 1, further comprising a controller in communication with the solar collector panel configured to direct the plurality of reflector elements to be optimally oriented to reflect sunlight toward the mirror.

6. A novel lighting system comprising:
a solar collector panel comprising a plurality of reflector elements configured to track and be oriented optimally to receive light from the sun and reflect the received light toward a skylight structure in a roof of a building;
the skylight incorporating a dichroic mirror oriented to receive the reflected light from the solar collector panel, the dichroic mirror being configured to reflect visible light downward into the building and pass through invisible light;
a photovoltaic panel configured to receive the invisible light that passed through the dichroic mirror and convert it to electricity; and
a controller in communication with the solar collector panel configured to direct the plurality of reflector elements to be optimally oriented to reflect sunlight toward the dichoric mirror.

7. The novel lighting system of claim 6, wherein the dichoric mirror is disposed in the skylight having reflective sides forming a reflective tunnel in the roof of the building.

8. The novel lighting system of claim 6, further comprising a battery storage system coupled to the photovoltaic panel configured to store the generated electricity.

9. A novel lighting system comprising:
a solar collector panel comprising a plurality of reflector elements configured to track and be oriented optimally to receive electromagnetic radiation from the sun and reflect the received electromagnetic radiation toward a skylight in a roof of a building; and
the skylight comprising a transparent window pane oriented toward the solar collector panel to allow the reflected electromagnetic radiation to impinge on a mirror disposed in the skylight and configured to receive the reflected electromagnetic radiation from the solar collector panel and reflect the received electromagnetic radiation downward into the building.

10. The novel lighting system of claim 9, wherein the mirror is disposed in the skylight having reflective sides forming a reflective tunnel in the roof of the building.

11. The novel lighting system of claim 9, further comprising a controller in communication with the solar collector panel configured to direct the plurality of reflector elements to be optimally oriented to reflect sunlight toward the mirror.

12. The novel lighting system of claim 9, wherein the mirror comprises a dichroic mirror oriented to receive the reflected light from the solar collector panel, the dichroic mirror being configured to reflect visible light downward into the building and pass through invisible light.

13. The novel lighting system of claim 12, further comprising a photovoltaic panel configured to receive the invisible light that passed through the dichroic mirror and convert it to electricity.

14. The novel lighting system of claim 13, further comprising a battery storage system coupled to the photovoltaic panel configured to store the generated electricity.

15. The novel lighting system of claim 9, wherein the solar collector panel comprises the plurality of reflector elements arranged in a plurality of reflector arrays, each reflector array arranged along a longitudinal axis and pivotally mounted to at least one elongated member parallel to the longitudinal axis, where the plurality of reflector elements in each reflector array being configured to pivot simultaneously in unison; and
each of the plurality of reflector arrays being mounted to rotate about the longitudinal axis independently of the other reflector arrays, where each of the plurality of reflector elements in a reflector array being configured to rotate about the longitudinal axis simultaneously in unison.
